(19) United States
(12) Patent Application Publication
(10) Pub. No.: US 2011/0094577 A1
(43) Pub. Date: Apr. 28, 2011

(54) CONDUCTIVE METAL OXIDE FILMS AND PHOTOVOLTAIC DEVICES

(76) Inventors: Dilip Kumar Chatterjee, Sugarland, TX (US); Curtis Robert Fekety, Corning, NY (US); Lenwood Lynell Fields, Painted Post, NY (US); Zhen Song, Painted Post, NY (US); Lili Tian, Corning, NY (US); Ji Wang, Painted Post, NY (US)

(21) Appl. No.: 12/887,761

(22) Filed: Sep. 22, 2010

Related U.S. Application Data
(60) Provisional application No. 61/255,583, filed on Oct. 28, 2009.

(51) Int. Cl. H01L 31/0216; B32B 5/00; B32B 17/06; B32B 18/00; B32B 15/04; B32B 27/06; C01B 11/00; C01G 19/02

(52) U.S. Cl. 136/256; 428/336; 428/432; 428/446; 428/469; 428/702; 423/472; 423/618; 423/608; 423/305; 423/605

(57) ABSTRACT

Article comprising a substrate; and a conductive metal oxide film adjacent to a surface of the substrate, wherein the conductive metal oxide film has an electron mobility (cm²/V-s) of 35 or greater are described. Photovoltaic devices comprising conductive metal oxide films are also described.

This application claims priority to U.S. Provisional Application No. 61/255,583 filed on Oct. 28, 2009.

### BACKGROUND

1. Field

Embodiments relates to conductive metal oxide films, articles comprising the conductive metal oxide films, and more particularly to photovoltaic devices comprising the conductive metal oxide films.

2. Technical Background

Transparent and/or electrically conductive film coated glass is useful for a number of applications, for example, in display applications such as the back plane architecture of display devices, for example, liquid crystal displays (LCD), and organic light-emitting diodes (OLED) for cell phones.

Transparent and/or electrically conductive film coated glass is also useful for solar cell applications, for example, as an electrode for some types of photovoltaic cells and in many other rapidly growing industries and applications. Transparent conductive oxides (TCO) are widely used in LCD display panels, Low-E windows, and most recently photovoltaic (PV) cells, E-papers, and in many other industrial applications. Though, cadmium oxide (CdO) is historically the first TCO discovered around 1907, today the most used TCOs are indium tin oxide (ITO) and fluorine doped tin oxide (FTO) found in the various display panels and the low-E windows, respectively.

TCOs are wide-band semiconductors in nature (hence the visible transmission and conductivity); and are mostly n-type with Fermi-level, ΔE˜kT, right below the conduction band minimum. The first useful p-type TCO (i.e., CuAlO₂) was realized later in 1997 and the field of next-generation “transparent electronics” has since emerged. However, there is a need for high performing TCOs as transparent electrodes in thin film PV technology that has drawn much of the attention lately.

In this regard, one of the most recent developments is in thin-film silicon tandem PV cells, which calls for an application-specific TCO with light trapping capability for improved solar-light absorption in the micro-crystalline silicon layer in order to increase cell efficiency. Commercially available textured FTO on soda-lime glass is an example of an FTO currently used in PV cells.

It would be advantageous to develop a conductive metal oxide film coated glass useful for TCO applications, for example, for photovoltaic applications.

### SUMMARY

Conductive metal oxide films as described herein, address one or more of the above-mentioned disadvantages of the conductive metal oxide films, in particular, when the films comprise tin oxide.

One embodiment is an article comprising a substrate; and a conductive metal oxide film adjacent to a surface of the substrate, wherein the conductive metal oxide film has an electron mobility (cm²/V-s) of 35 or greater.

Another embodiment is a photovoltaic device comprising a substrate; a conductive metal oxide film adjacent to the substrate, wherein the conductive metal oxide film has an electron mobility (cm²/V-s) of 35 or greater; and an active photovoltaic medium adjacent to the conductive metal oxide film.

Additional features and advantages of the invention will be set forth in the detailed description which follows, and in part will be readily apparent to those skilled in the art from the description or recognized by practicing the invention as described in the written description and claims hereof, as well as the appended drawings.

It is to be understood that both the foregoing general description and the following detailed description are merely exemplary of the invention, and are intended to provide an overview or framework to understanding the nature and character of the invention as it is claimed.

The accompanying drawings are included to provide a further understanding of the invention, and are incorporated in and constitute a part of this specification. The drawings illustrate one or more embodiment(s) of the invention and together with the description serve to explain the principles and operation of the invention.

### BRIEF DESCRIPTION OF THE DRAWINGS

The invention can be understood from the following detailed description either alone or together with the accompanying drawings.

FIGS. 1A-1C are cross sectional scanning electron microscope (SEM) images of the films made according to some embodiments.

FIGS. 2A-2B are cross sectional scanning electron microscope (SEM) images of the films made according to some embodiments.

FIG. 2C is a cross sectional SEM image of an exemplary film.

FIG. 2D is a top down SEM image of an exemplary film.

FIG. 3 is an illustration of features of a photovoltaic device, according to one embodiment.

FIG. 4 is a graph of total and diffuse transmittance values for an exemplary article.

FIG. 5 is a graph of total and diffuse transmittance values for two exemplary articles.

FIG. 6 is a graph of Bidirectional light Transmission (Reflection) Distribution Functions (BTDFs) for an exemplary article.

FIG. 7 is a cross sectional SEM image of an exemplary film.

### DETAILED DESCRIPTION

Reference will now be made in detail to various embodiments of the invention, an example of which is illustrated in the accompanying drawings.

As used herein, the term “volumetric scattering” can be defined as the effect on paths of light created by inhomogeneities in the refractive index of the materials that the light travels through.

As used herein, the term “surface scattering” can be defined as the effect on paths of light created by interface roughness between layers in a photovoltaic cell.

As used herein, the term “substrate” can be used to describe either a substrate or a superstrate depending on the configuration of the photovoltaic cell. For example, the substrate is a superstrate, if when assembled into a photovoltaic cell, it is on the light incident side of a photovoltaic cell. The superstrate can provide protection for the photovoltaic materials from impact and environmental degradation while allowing transmission of the appropriate wavelengths of the solar spectrum. Further, multiple photovoltaic cells can be arranged into a photovoltaic module.

As used herein, the term “adjacent” can be defined as being in close proximity. Adjacent structures may or may not be in physical contact with each other. Adjacent structures can have other layers and/or structures disposed between them.

As used herein, the term “planar” can be defined as having a substantially topographically flat surface.

Although exemplary numerical ranges are described in the embodiments, each of the ranges can include any numerical value including decimal places within the range including each of the ranges endpoints.

One embodiment is an article comprising a substrate; and a conductive metal oxide film adjacent to a surface of the substrate, wherein the conductive metal oxide film has an electron mobility (cm²/V-s) of 35 or greater. In one embodiment, the conductive metal oxide film has an electron mobility (cm²/V-s) of 40 or greater, for example, 45 or greater, for example 50 or greater, for example, 55 or greater. In another embodiment, the conductive metal oxide film has an electron mobility (cm²/V-s) in the range of from 35 to 60.

The conductive metal oxide film, in one embodiment, has a carrier concentration (1/cm³) of 9.00×10²⁰ or greater.

The conductive metal oxide film, in one embodiment, has a median porosity of 5 percent or greater, for example, from 5 to 20 percent. The porosity can be described as voids around the grain boundaries in the film.

In one embodiment, the conductive metal oxide film comprises chlorine doped tin oxide, fluorine and chlorine doped tin oxide, fluorine doped tin oxide, cadmium doped tin oxide, titanium doped tin oxide, indium doped tin oxide, aluminum doped tin oxide, niobium doped tin oxide, tantalum doped tin oxide, vanadium doped tin oxide, phosphorus doped tin oxide, zinc doped tin oxide, magnesium doped tin oxide, manganese doped tin oxide, copper doped tin oxide, cobalt doped tin oxide, nickel doped tin oxide, aluminum doped zinc oxide, zinc oxide, or combinations thereof.

The conductive metal oxide film, in one embodiment, has a thickness of 3 microns or less, for example, 2 microns or less, for example, 1 micron or less, for example, 500 nanometers or less, for example, 100 nanometers or less, for example, 50 nanometers or less. In another embodiment, the film has a thickness in the range of from 10 nanometers to 1000 nanometers, for example, 10 nanometers to 500 nanometers.

The conductive metal oxide film is transparent, in some embodiments. The conductive film, in some embodiments, has a haze value of 55 percent or less, for example, 50 percent or less, for example, 40 percent or less. The conductive film can have a haze value of greater than 0 to 55 percent and maintain a high transmission value. The conductive metal oxide film can have a transmission value of 75% or greater in the visible spectrum.

A photovoltaic device, a display device, or an organic light-emitting diode can comprise the article, according to some embodiments.

According to one embodiment, the substrate comprises a glass layer. In another embodiment, the substrate is a glass substrate.

The conductive metal oxide films as disclosed herein can be made, for example, by providing a solution comprising a metal oxide precursor and a solvent, preparing aerosol droplets of the solution, and applying the aerosol droplets to a heated glass substrate, converting the metal oxide precursor to a metal oxide to form a metal oxide film on the glass substrate. The metal oxide precursor is a metal halide, in some embodiments. The solution can comprise water or in some cases is water.

Hydrolysis reactions are possible when the solvent comprises water. In these reactions, the metal halide reacts with water and converts to its respective oxide. When the solvent comprises only alcohol, a flash reaction can occur in the presence of oxygen where the alcohol is evaporated and/or combusted. The metal halide, for example, tin chloride reacts with the oxygen in an oxidation reaction to form its respective oxide. In one embodiment, the oxide sinters to form a conductive metal oxide film.

When the metal oxide precursor is a tin precursor, the tin precursor is selected from tin chloride (SnCl₂), tin tetrachloride (SnCl₄), and combinations thereof, in one embodiment. The tin precursor can be in an amount of from 5 to 20 weight percent of the solution, for example, 13 weight percent or more of the solution.

The solution can further comprise a dopant precursor. The dopant precursor can be selected from HF, NH₄F, SbCl₃, and combinations thereof, for example.

The aerosol droplets can be prepared by atomizing the solution. A gas, for example, argon, helium, nitrogen, carbon monoxide, hydrogen in nitrogen and/or oxygen can be flowed through the solution in an atomizer. Ambient air can be flowed through the atomizer in addition to or instead of the gas. In some embodiments, the velocity of the atomized solution can be between 2 liters per minute (L/min) and 7 L/min, for example, 3 L/min. The aerosol droplets, in one embodiment, have median droplet size of less than 1 micron in diameter, for example, a droplet size of from 10 nanometers to 999 nanometers, for example, 50 nanometers to 450 nanometers.

The aerosol droplets can be sprayed from one or more sprayers adapted to receive the aerosol droplets from the atomizer and located proximate to the glass substrate.

The aerosol sprayer can be of any shape depending on the shape of the glass substrate to be coated and the area of the glass substrate to be coated. Spraying the aerosol droplets can comprise translating the sprayer(s) in one or more directions relative to the glass substrate, for example, in an X direction, a Y direction, a Z direction or a combination thereof in a three dimensional Cartesian coordinate system.

The aerosol droplets can be applied by flowing the aerosol droplets into a furnace. The glass substrates can be positioned in the furnace so as to receive the flow of aerosol droplets such that the droplets are deposited onto the glass substrates.

In one embodiment, the substrate comprises a material selected from glass, ceramic, glass ceramic, polymer, plastic, metal, for example, stainless steel and aluminum, or combinations thereof. In one embodiment, the substrate is planar, circular, tubular, a fiber, or a combination thereof.

In one embodiment, the substrate is in a form selected from a glass sheet, a glass slide, a textured glass substrate, a glass sphere, a glass cube, a glass tube, a honeycomb, a glass fiber, and a combination thereof. In another embodiment, the glass substrate is planar and can be used as a superstrate or substrate in a thin-film photovoltaic device.

According to one embodiment, the method comprises applying the aerosol droplets to the glass substrate that is at a temperature of from 300 degrees Celsius to 530 degrees Celsius. In some applications, the upper end of the temperature range is dependent on the softening point of the glass substrate. The conductive films are typically applied at a temperature below the softening point of the glass substrate. According to one embodiment, the conductive film is formed at ambient pressure.

Evaporation of the solvent in the aerosol droplets can occur during transportation and/or deposition of the aerosol droplets onto the substrate. Evaporation of the solvent, in some embodiments can occur after the aerosol droplets have been deposited onto the substrate. Several reactive mechanisms can be realized by the disclosed methods, for example, a homogeneous reaction between the metal halide and the solvent in the aerosol droplets, a heterogeneous reaction between the solvent and/or the gas with the oxide in the formed or forming oxide(s), and/or oxide nucleus bonding with surface of the substrate and crystallization.

By controlling the aerosol transportation temperature, evaporation of the solvent from the aerosol droplets can be controlled and thus, the mean aerosol droplet size can be controlled to make the deposition more efficient and/or more uniform. Controlling the transportation temperature can enhance reactions between solvent and metal halide, and the formation of solid nuclei inside the droplets.

Heating the substrate can provide enough activation energy for the formation of oxides. Meanwhile the remaining solvent evaporates from the heated substrate. Heating can also provide energy for the deposited small particles to crystallize and form bigger crystals.

The solution can be made by dissolving precursors for the oxide(s) and/or the dopant(s) into a solvent. For example, to prepare a SnO₂ based transparent conductive oxide (TCO) film, SnCl₄ and SnCl₂ can be used as Sn precursors. HF, NH₄F, SbCl₃, etc. can be used as F and Sb dopant precursors. The solvent for these precursors can be water. When using water as the solvent, SnCl₂ or SnCl₄ as the precursor to make SnO₂, the SnCl₂ or SnCl₄ is hydrolyzed by water and this reaction occurs in solution, in droplets and on the deposited surface. The produced HCl enhances the fully oxidation of Sn by water. The dopants (such as F and Sb) can be added into the SnO₂ lattice during the deposition process. The remnant Cl on Sn can also remain in the lattice and form Cl doping.

During the deposition of the aerosol droplets the following hydrolysis reaction occurred:

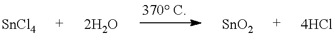

Cl was also doped into SnO₂ lattice. If other dopants co-exist in the solution, such as HF, NH₄F or SbCl₃, F or Sb, the dopants can also be incorporated into the SnO₂ lattice. This doping helps to form a stable conductive metal oxide film.

The conductive films can be heat treated after their formation. The heat treatment can be performed in air at temperatures ranging from less than 250° C., for example, from 150° C. to 250° C., for example 200° C. Heat treating can be performed in an inert atmosphere, for example, in nitrogen which may allow for higher heat treating temperatures, for example, greater than 250° C., for example, 400° C.

The conductivity of the conductive films can be further improved by post heat treatment. This heat treatment can remove the adsorbates from the grain boundaries and the particle surfaces, and releases the trapped free electrons. The post treatment temperature should be below the SnO₂ oxidation temperature, if the treatment is in air.

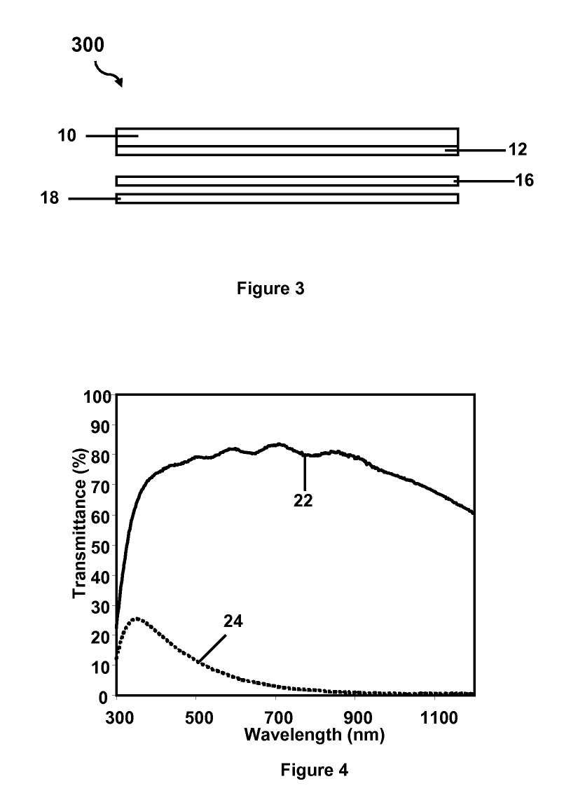

Another embodiment is a photovoltaic device, features 300 of which are shown in FIG. 3. The photovoltaic device comprises a substrate 10; a conductive metal oxide film 12 adjacent to the substrate; and an active photovoltaic medium 16 adjacent to the conductive metal oxide film, wherein the conductive metal oxide film has an electron mobility (cm²/V-s) of 35 or greater. In one embodiment, the conductive metal oxide film has an electron mobility (cm²/V-s) of 40 or greater, for example, 45 or greater, for example 50 or greater, for example, 55 or greater. In another embodiment, the conductive metal oxide film has an electron mobility (cm²/V-s) in the range of from 35 to 60.

According to one embodiment, the active photovoltaic medium is in physical contact with the conductive metal oxide film.

In another embodiment, the photovoltaic device further comprises a counter electrode 18 located on an opposite surface of the active photovoltaic medium as the conductive metal oxide film. In one embodiment, the counter electrode is in physical contact with the active photovoltaic medium.

The active photovoltaic medium can comprise multiple layers, for example, an amorphous silicon layer and a microcrystalline silicon layer.

In one embodiment, the active photovoltaic medium comprises cadmium telluride, copper indium gallium diselinide, amorphous silicon, crystalline silicon, microcrystalline silicon, or combinations thereof.

In one embodiment, the substrate is glass.

In another embodiment, the substrate is planar. The substrate, in one embodiment, is a planar glass sheet.

The conductive metal oxide film, in one embodiment, has a carrier concentration (1/cm³) of 9.00×10²⁰ or greater.

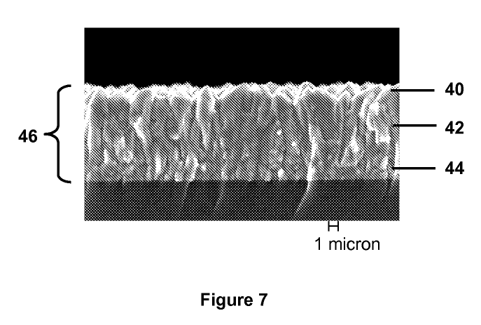

The conductive metal oxide film, in one embodiment, has a median porosity of 5 percent or greater, for example, from 5 to 20 percent. The porosity can be described as voids around the grain boundaries in the film. FIG. 7 is an SEM image of an exemplary film. The film 46 is a F and Cl co-doped tin oxide. In one embodiment, as shown in FIG. 7, the porosity of the film may vary from a higher relative porosity at the substrate film interface 44 to a relatively more dense lower porosity in the middle 42 of the film to a higher relative porosity on the surface 40 of the film.

The conductive metal oxide film is transparent, in some embodiments. The conductive film, in some embodiments, has a haze value of 55 percent or less, for example, 50 percent or less, for example, 40 percent or less. The conductive film can have a haze value of greater than 0 to 55 percent and maintain a high transmission value. The conductive metal oxide film can have a transmission value of 75% or greater in the visible spectrum.

In one embodiment, the active photovoltaic medium is in physical contact with the conductive metal oxide film.

The device, according one embodiment, further comprises a counter electrode in physical contact with the active photovoltaic medium and located on an opposite surface of the active photovoltaic medium as the conductive metal oxide film.

According to one embodiment, the conductive metal oxide film comprises chlorine doped tin oxide, fluorine and chlorine doped tin oxide, fluorine doped tin oxide, cadmium doped tin oxide, titanium doped tin oxide, indium doped tin oxide, aluminum doped tin oxide, niobium doped tin oxide, tantalum doped tin oxide, vanadium doped tin oxide, phosphorus doped tin oxide, zinc doped tin oxide, magnesium doped tin oxide, manganese doped tin oxide, copper doped tin oxide, cobalt doped tin oxide, nickel doped tin oxide, aluminum doped zinc oxide, zinc oxide, or combinations thereof.

### EXAMPLES

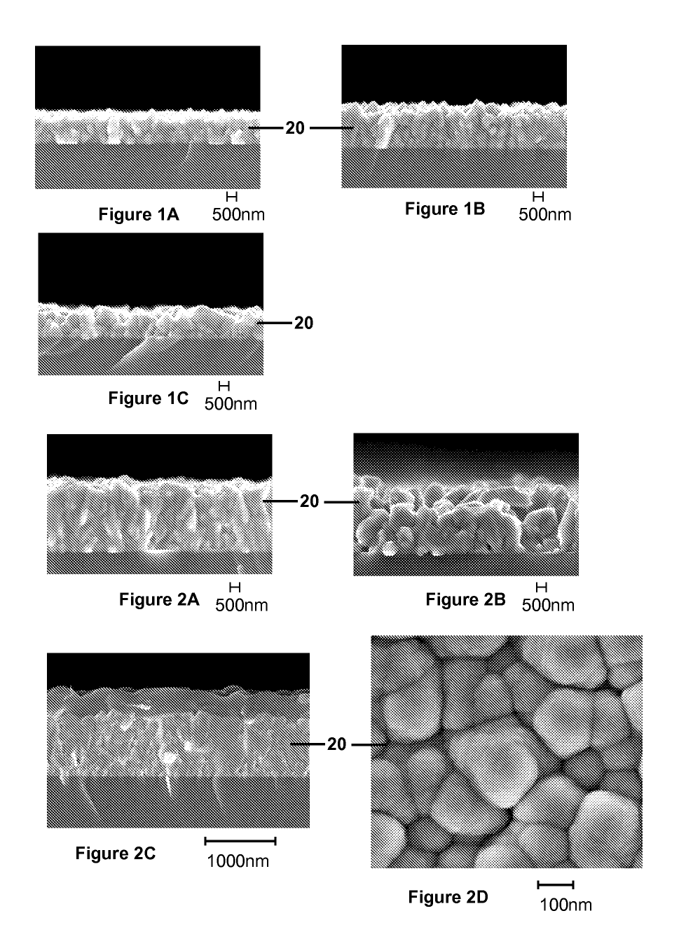

Two concentrations of SnCl₄ water solutions were prepared, one 0.27M and the other 0.6M. Hydrofluoric acid (HF) was added for fluorine doping with an F/Sn atomic ratio of 60:40. A TSI six-jet atomizer was used for aerosol generation with two of the jets opened. Nitrogen (N₂) was used for aerosol generation and as the carrier gas. The N₂ pressure was set to 30 psi for both the aerosol generation and the carrier gas. The generated aerosol droplets had diameters of from 0.4 to 4 microns. The FTO films were deposited for 15 min at different temperatures ranging from 350° C. to 600° C. Cross sectional SEM images of the films 20 made with 0.27M solution are shown in FIGS. 1A-1C. The deposition temperatures were 360° C., 380° C., and 530° C. respectively. Cross sectional SEM images of the films 20 made with 0.6M solution are shown in FIGS. 2A-2B. The deposition temperatures were 380° C. and 530° C. respectively. A cross sectional SEM image of an exemplary film 20 is shown in FIG. 2C. FIG. 2D is a top down SEM image of an exemplary film 20. These two figures show amorphous silicon films deposited on an FTO film, according to one embodiment.

For 0.27M SnCl₄ solution deposition as shown in FIGS. 1A-1C, the film 20 surface roughness is consistent with the particle size that composes the films. (The particle size is smaller for lower temperature deposition). The film thickness increases with the coating temperature from 200 nm coated at 360° C. to 250 nm coated at 380° C. Higher precursor concentration results in larger grain size.

FIG. 4 is a graph of total, shown by line 22, and diffuse, shown by line 24, transmittance values for an exemplary article. The conductive film in this example is a fluorine doped tin oxide.

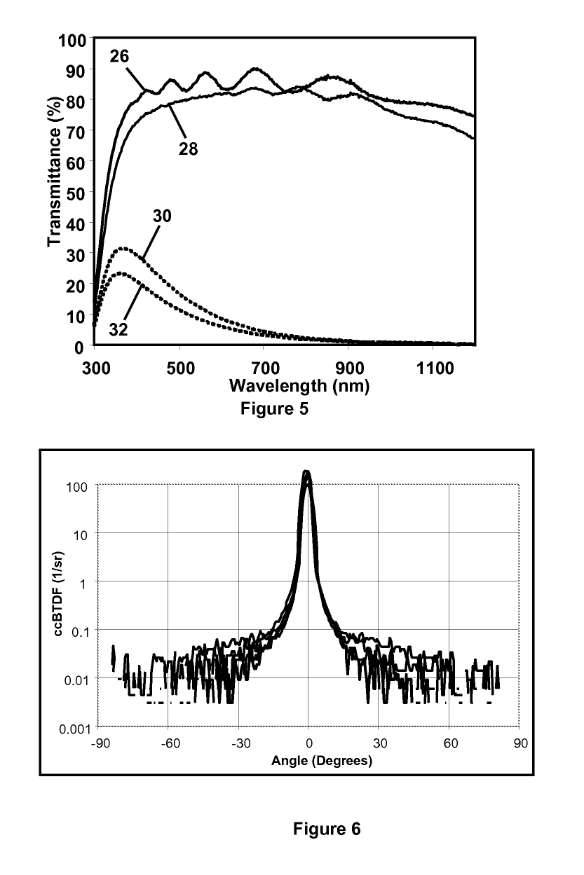

FIG. 5 is a graph of total and diffuse transmittance values for two exemplary articles. Lines 26 and 32 show total and diffuse transmittance values, respectively, of an exemplary article. Lines 28 and 30 show total and diffuse transmittance values, respectively, of an exemplary article.

FIG. 6 is a graph of Bidirectional light Transmission (Reflection) Distribution Functions (BTDFs) for an exemplary article.

The film conductivities were measured as sheet resistance. An increase of the film electrical resistance at higher coating temperatures was seen.

Sample photovoltaic cells were made using exemplary articles, for example, fluorine doped tin oxide (FTO) films made by nano-chemical liquid deposition (NCLD) methods previously described. The sample sizes were 1 inch by 1 inch. The properties shown in Table 1 were measured. NCLD-FTO shows a possible advantage over some conventionally available ITO films with high electron mobility at high carrier concentrations. An amorphous silicon PV cell was made using the conductive metal oxide film and yielded a 7.2% quantum efficiency (QE). Further, the FTO had a resistivity of ˜1.7×10-4 Ω·cm which is close to conventionally available indium doped tin oxide (ITO) films. Transmission was in the range of from 80% to 85% in the visible spectrum.

TABLE 1

| | Sheet | Carrier | Hall |
|---|---|---|---|
| | Resistance | Concentration | Mobility |
| Type of FTO | (Ω/sq) | (1/cm³) | (cm²/V-s) |
| NCLD | 1.7 | 9.39 × 10²⁰ | 45.6 |

Conductive metal oxide films are useful in photovoltaic devices due in part to the transparency and/or conductivity of the films. In photovoltaic applications, it is advantageous for the films to be not only conductive, but also transparent in a certain wavelength window within which the photon energy is higher than the bandgap of the active light absorber (active photovoltaic material) layer in photovoltaic devices.

In transparent conductive oxides, both electrical properties and optical properties can be described by the Drude model which explains the thermal as well as the electrical and optical properties of metals by the movement of both free and bound electrons. The conductivity and the plasma frequency of the conductive metal oxides are described by the following formulas, respectively:

$$σ = N e μ = ( \frac{{ɛ}_{∞}}{4 π} ) {ω}_{p}^{2} τ {ω}_{p} = \sqrt{\frac{N {e}^{2}}{{ɛ}_{0} {m}^{*} {ɛ}_{r}}} μ = \frac{eτ}{{m}^{*}}$$

wherein σ is the conductivity, ωₚ is the plasma frequency, m* is the effective mass of the electron, μ is the optical mobility of the free electron, e is the electron charge, τ is the relaxation time of the electron, and N is the density of the free electron.

For highly conductive and highly transparent conductive oxides with a wide transparency window, the materials should have less free electrons, heavier effective electron mass, and higher mobility of the free carrier.

The optical spectra, ellipsometry and reflection IR spectra of the conductive F doped SnO₂, Cl doped SnO₂ films made by NCLD methods were measured and the data suggests that the effective electron mass in the Cl doped SnO₂ film is about ˜0.34 mₑ which is heavier than that in F doped SnO₂ film (˜0.28 mₑ). This would move the plasma frequency of the Cl doped SnO₂ film to further into the infrared region than the plasma frequency of the F doped SnO₂ film when the films have the same level of free electron carrier density. This could lead to a wider transparent window in Cl doped SnO₂ films than F doped SnO₂ films.

Table 2. shows the effective electron mass, free electron density as well as optical mobility of exemplary Cl doped SnO₂, fluorine doped SnO₂, as well as fluorine and chlorine co-doped SnO₂ films made by NCLD methods described herein.

TABLE 2

| | Relaxation | | λₘᵢₙ | | | |
|---|---|---|---|---|---|---|
| | Time, cal | λ_{min, cal} | Measured | m* | N | μ_{optical} |
| Film | (sec) | (μm) | (μm) | (\dot{mₑ}) | (cm⁻³) | (cm²/Vs) |
| Cl: SnO₂ | 1.62E−14 | 3.21 | 3.20 | 0.34 | 1.13E+20 | 83.3 |
| (Cl, F): SnO₂ | 7.31E−15 | 1.49 | 1.49 | 0.29 | 4.39E+20 | 44.9 |
| F: SnO₂ | 5.98E−15 | 1.64 | 1.63 | 0.28 | 3.69E+20 | 37.3 |

One is often interested in obtaining the highest electrical conductivity possible. Electrical conductivity can be defined by the following equation:

σ=qμn

wherein q is the charge on a single electron, μ is mobility and n is carrier concentration. Conductivity can be increased by either increasing mobility or increasing carrier concentration. However, it is not always easy to increase the carrier concentration. In addition, increasing the carrier concentration can decrease transmission though the material (especially in the near IR) and this can be important in thin film solar cells where as large a transmission as possible is advantageous, and at the same time, it is advantageous for the conductivity to be as large as possible because this assures that the transparent conducting oxide will not have a large series resistance which can degrade the power conversion efficiency of solar cells. Therefore, it is advantageous to have the mobility as large as possible.

Table 3 shows the mobility for exemplary films, samples 1 through 10. The exemplary films were fluorine doped tin oxide films.

TABLE 3

| | | | Sheet | | |
|---|---|---|---|---|---|
| | | | Carrier | Sheet | |
| Sample | | Mobility | Density | Resistance | |
| ID | Material | (cm²/V-s) | (1/cm²) | (Ω/Square) | Geometry |
| 1 | FTO | 57.1 | 9.49E+16 | 1.15 | |
| 2 | FTO | 55.6 | 9.81E+16 | 1.15 | |
| 3 | FTO | 42.7 | 5.54E+16 | 2.65 | |
| 4 | FTO | 39 | 3.45E+16 | 4.64 | |
| 5 | FTO | 47.4 | 4.88E+16 | 2.7 | 2.5″ × 2.5″ |
| 6 | FTO | 42.4 | 6.27E+16 | 2.35 | 2.5″ × 2.5″ |
| 7 | FTO | 49.5 | 8.32E+16 | 1.52 | 2.5″ × 2.5″ |
| 8 | FTO | 45.3 | 8.94E+16 | 1.54 | 2.5″ × 2.5″ |
| 9 | FTO | 46.8 | 7.82E+16 | 1.71 | 2.5″ × 2.5″ |
| 10 | FTO | 47.1 | 8.91E+16 | 1.49 | 1″ × 1″ |

The mobility and carrier density measurements were obtained using a typical Hall Measurement system. The magnetic field strength was 0.2 Tesla and the van der Pauw geometry was used. The measurements were performed at room temperature. A Hall scattering factor of unity was assumed. The hall scattering factor typically varies between 1 and 2 and depends on the scattering mechanisms in the material. It is typical to report hall mobilities with the assumption that the Hall scattering factor is unity.

It will be apparent to those skilled in the art that various modifications and variations can be made to the present invention without departing from the spirit or scope of the invention. Thus, it is intended that the present invention cover the modifications and variations of this invention provided they come within the scope of the appended claims and their equivalents.

What is claimed is:

1. An article comprising a substrate; and a conductive metal oxide film adjacent to a surface of the substrate, wherein the conductive metal oxide film has an electron mobility (cm²/V-s) of 35 or greater.

2. The article according to claim 1, wherein the conductive metal oxide film has a carrier concentration (1/cm³) of 9.00×10²⁰ or greater.

3. The article according to claim 1, wherein the conductive metal oxide film has a median porosity of 5 or greater percent.

4. The article according to claim 1, wherein the conductive metal oxide film has a transmission of 75% or greater in the visible spectrum.

5. The article according to claim 1, wherein the conductive metal oxide film has an average thickness of 3 microns or less.

6. The article according to claim 1, wherein the conductive metal oxide film comprises chlorine doped tin oxide, fluorine and chlorine doped tin oxide, fluorine doped tin oxide, cadmium doped tin oxide, titanium doped tin oxide, indium doped tin oxide, aluminum doped tin oxide, niobium doped tin oxide, tantalum doped tin oxide, vanadium doped tin oxide, phosphorus doped tin oxide, zinc doped tin oxide, magnesium doped tin oxide, manganese doped tin oxide, copper doped tin oxide, cobalt doped tin oxide, nickel doped tin oxide, or combinations thereof.

7. The article according to claim 1, wherein the substrate comprises a material selected from glass, ceramic, glass ceramic, polymer, plastic, metal, or combinations thereof.

8. The article according to claim 1, wherein the substrate is planar, circular, tubular, a fiber, or a combination thereof.

9. A photovoltaic device, a display device, or an organic light-emitting diode comprising the article according to claim 1.

10. A photovoltaic device comprising
a substrate;
a conductive metal oxide film adjacent to a surface of the substrate, wherein the conductive metal oxide film has an electron mobility (cm²/V-s) of 35 or greater; and
an active photovoltaic medium adjacent to the conductive metal oxide film.

11. The device according to claim 10, wherein the substrate is glass.

12. The device according to claim 10, wherein the substrate is planar.

13. The device according to claim 10, wherein the conductive metal oxide film has a carrier concentration (1/cm³) of 9.00×10²⁰ or greater.

14. The device according to claim 10, wherein the conductive metal oxide film has a transmission of 75% or greater in the visible spectrum.

15. The device according to claim 10, wherein the conductive metal oxide film has a median porosity of from 5 or greater percent.

16. The device according to claim 10, wherein the active photovoltaic medium is in physical contact with the conductive metal oxide film.

17. The device according to claim 10, further comprising a counter electrode in physical contact with the active photovoltaic medium and located on an opposite surface of the active photovoltaic medium as the conductive metal oxide film.

18. The device according to claim 10, wherein the active photovoltaic medium comprises multiple layers.

19. The device according to claim 10, wherein the active photovoltaic medium comprises cadmium telluride, copper indium gallium diselenide, amorphous silicon, crystalline silicon, microcrystalline silicon, or combinations thereof.

20. The device according to claim 10, wherein the conductive metal oxide film comprises chlorine doped tin oxide, fluorine and chlorine doped tin oxide, fluorine doped tin oxide, cadmium doped tin oxide, titanium doped tin oxide, indium doped tin oxide, aluminum doped tin oxide, niobium doped tin oxide, tantalum doped tin oxide, vanadium doped tin oxide, phosphorus doped tin oxide, zinc doped tin oxide, magnesium doped tin oxide, manganese doped tin oxide, copper doped tin oxide, cobalt doped tin oxide, nickel doped tin oxide, or combinations thereof.
